(19) United States
(12) Patent Application Publication
(10) Pub. No.: US 2016/0171794 A1
(43) Pub. Date: Jun. 16, 2016

(54) Method and Devices for Providing Information for the Purposes of Maintaining and Servicing a Battery

(71) Applicants: ROBERT BOSCH GMBH, Stuttgart (DE); SAMSUNG SDI CO., LTD., Yongin-si, Gyeonggi-do (KR)

(72) Inventor: Christoph Brochhaus, Aachen (DE)

(21) Appl. No.: 14/892,278

(22) PCT Filed: May 9, 2014
(86) PCT No.: PCT/EP2014/059512

§ 371 Date: Nov. 19, 2015

(30) Foreign Application Priority Data
May 22, 2013 (DE) 10 2013 209 446.9

(51) Int. Cl. G07C 5/08; G01R 31/36; B60L 11/18; H01M 10/42

(52) U.S. Cl. CPC G07C 5/085; H01M 10/425; G01R 31/3651; B60L 11/1851; G07C 5/0808; H01M 2220/20; H01M 2010/4271

(57) ABSTRACT

The disclosure relates to a method for providing information for the purposes of maintaining and servicing a battery. The battery comprises a control unit, which has a non-volatile memory, and a plurality of battery units. The method comprises a) detecting and quantizing usage data of the battery units; b) forming a histogram, which comprises frequency values of an occurrence of certain values of individual quantized usage data or values derived therefrom; c) determining at least one additional information carrier, which is configured for a validity check of the histogram; and d) storing the histogram and the additional information carrier in the non-volatile memory of the control unit.

### PRIOR ART

The invention concerns a method for providing information for maintenance and servicing purposes for a battery comprising a plurality of battery units, wherein usage data of the battery units are recorded and quantized and wherein histograms are formed comprising frequency values for the occurrence of certain values of the individual quantized usage data or values derived therefrom.

The invention further concerns a method that provides the information to decentralized module control units.

Furthermore, a data structure with such information is specified, as well as a computer program and a battery management system, which are in particular provided to perform the method. Furthermore, a battery and a motor vehicle with such a battery are specified.

Electronic control units are increasingly used in the automobile sphere nowadays, examples thereof being engine control units or control units for the ABS or the airbag. A current focus of research for electrically driven vehicles is the development of powerful battery packs with associated battery management systems, i.e. control units, that are provided with software for monitoring battery functionality. Battery management systems guarantee inter alia the safe and reliable operation of the battery cells and battery packs used. They monitor and control currents, voltages, temperatures, insulation impedances and other variables for individual cells and/or the entire battery pack. Using said variables, management functions can be implemented that increase the life, reliability and safety of the battery system.

DE 10 2010 031 337 A1 discloses a method for determining the expected life of battery cells. For this physical variables and/or the number of performances of processes occurring in the battery cells are determined for a plurality of operating cycles and the frequency of the occurrence of certain values of the physical variables and/or the frequency of the number of the performances of at least one certain process are stored. In this way inter alia cell defects can be detected in a timely manner, can be prevented and accurate evidence regarding the expected life of the battery cell can be obtained.

U.S. Pat. No. 5,552,999 discloses a method for monitoring the power consumption of a battery in a battery pack, wherein a histogram is generated.

### DISCLOSURE OF THE INVENTION

According to a first aspect, a method according to the invention for providing information for maintenance and servicing purposes for a battery comprising a control unit with a non-volatile memory and a plurality of battery units comprises the following steps:
a) Recording and quantizing usage data for the battery units;
b) Forming a histogram comprising frequency values of the occurrence of certain values of the individual quantized usage data or values derived therefrom;
c) Determination of at least one additional information carrier that is provided for a validity check of the histogram; and
d) Storage of the histogram and the additional information carrier in the non-volatile memory of the control unit.

The method can be used with batteries comprising a central control unit with a non-volatile memory. In particular, the steps of the method c) and d) are preferably performed by the central control unit for this. The method can also be used for batteries comprising at least one battery module with an associated module control unit with a non-volatile memory. In particular, the steps of the method c) and d) are preferably performed by the module control unit here. It is particularly preferably provided that the steps c) and d) are performed both by the central control unit and also by the module control units.

According to a further aspect, a method according to the invention for providing information for maintenance and servicing purposes for a battery comprising at least one battery module with an associated module control unit and a central control unit, wherein at least one module control unit comprises a non-volatile memory, comprises the following steps:
i) Recording and quantizing usage data of battery units;
ii) Forming a histogram comprising the frequency values of the occurrence of certain values of the individual quantized usage data or values derived therefrom;
iii) Determination by the central control unit of at least one additional information carrier that is provided for a validity check of the histogram;
iv) Transmission of the histogram and of the at least one additional information carrier from the central control unit to a module control unit;
v) Validation of the histogram using the at least one additional information carrier by the module control unit;
vi) Storage of the histogram in the non-volatile memory of the module control unit.

Advantageously, with the method according to the invention a history of the battery usage is maintained, which can be read out and used both in the context of warranty claims and also for assessing the battery usage, for example for determining the expected life or the state of health (SOH) of the battery unit. Histograms are formed for this, wherein the histograms contain numbers of recordings of the respective quantized usage data item or values derived therefrom that can be assigned to the individual quantized usage data. The histograms are advantageously particularly suitable for determining the life and the state of health and the state of ageing of the battery unit. By using a counter for the driving cycles, moreover, conclusions can be drawn regarding the average battery unit usage per driving cycle. The histogram thus gives a general overview of the use of the battery during its life to date. Also in the context of warranty claims the histogram can be read out of the non-volatile memory of the relevant control unit and used to assess the usage of the battery.

Updating the histogram is carried out after each driving cycle. A histogram thus comprises the frequency values of the occurrence of certain values of the individual quantized usage data of the last driving cycle and the previous driving cycles. The events triggered at the start and end of the driving cycle can for example be charging pulses, a change of state of the battery from “drive” to “charge”, an analysis of a signal “charging active” or even an analysis of a change of state at terminal 15, i.e. of the ignition positive. The event triggering the start and the end of the driving cycle can also be defined by detection of the so-called battery balancing. The driving cycle can for example be defined such that it comprises or does not comprise a subsequent charging process.

Before, during or after the driving cycle an existing histogram is loaded from the non-volatile memory of the control unit. During the driving cycle a current histogram is preferably generated in the volatile memory of the control unit. After the driving cycle the current histogram and the existing histogram are combined to form an updated histogram and stored in the non-volatile memory of the control unit. Such a non-volatile memory is for example a so-called EEPROM, i.e. an electrically erasable, programmable read-only memory.

A recording rate of the usage data of the battery unit preferably has a defined value between 6/s and 6/h, preferably between 1/s and 1/min, particularly preferably 6/min or 1/min. Following the defined time intervals, for example the current temperature and the current voltage of the cells are recorded in the histogram. For measurement values such as temperature and SOC, other preferable sampling rates lie between 1/min and 6/h, in particular at approx. 1/min. For voltages a filtered value is preferably stored, for example an average value over a defined period of time, wherein preferable periods of time are also approx. 1 min. The recording rate of the respective usage data of the battery unit preferably lies in a range that supports on-board diagnosis (OBD).

The battery usage data comprise for example the temperature, the state of charge, the output current or the provided voltage. Usage data can also comprise variables derived therefrom, for example variables summed over time or integrated variables, variables multiplied together or otherwise aggregated variables, such as for example even the so-called state of health (SOH) of the battery in suitably quantifiable units. Moreover, the usage data can comprise difference values between minimum and maximum states, for example of states of charge, relative battery powers or number of performances of charge cycles and discharge cycles.

Derived values can for example mean relative frequencies, systematic shifts or weightings of the recordings of the usage data that are suitable for increasing the meaningfulness or comparative value of the recorded usage data.

The quantization of the recorded usage data means that reference points are defined that each constitute boundaries of intervals, and the recorded usage data are associated with the intervals. The intervals can be defined as of different sizes or uniform for this. For example, a temperature range between −40° C. and +80° C. can be defined and can be divided into intervals of 10° C., 5° C., 2° C. or 1° C. Regarding the size and number of the intervals, the memory occupied by the histogram on the one hand and the meaningfulness of the recorded usage data quantized in this way on the other hand are taken into account.

Advantageous developments and improvements of the method specified in the independent claims are possible as a result of the measures referred to in the dependent claims.

According to one embodiment, the additional information carrier is a check sum that is determined using the histogram and an individual key of the central control unit. For the case in which the battery comprises a plurality of battery modules with associated module control units, according to preferred embodiments the histogram and other additional information carriers are additionally stored in non-volatile memories of at least one module control unit. The further additional information carriers are also provided to perform validity checks of the histogram.

For the case in which the battery comprises a plurality of battery modules with associated module control units, according to one embodiment the additional information carrier is a check sum that is determined using the histogram and an individual key of at least one module control unit. The central control unit preferably detects at least one additional information carrier for each module control unit present and transmits the histogram with the additional information carrier to the respective module control unit. The respective module control unit validates the histogram using the additional information carrier and stores the validated histogram in its non-volatile memory.

For this it can be provided that the module control unit is provided in the factory with an individual that is stored in a non-volatile memory of the module control unit. During manufacture of the battery the individual key is read out by the central control unit from the individual module control unit and stored in the central control unit. Within the central control unit and the module control unit it can be provided that the key is subsequently stored in the memory in encrypted form so that it cannot be read out by an attacker.

According to an alternative embodiment, the module control units receive their individual keys during an initialization process, which is for example associated with a first start of the battery. In this case it can be provided that the individual module control units signal to the central control unit the lack of an individual key during the initialization, and that the key is then generated by the central control unit and communicated to the respective module control unit, where it is stored.

For the case in which a module is replaced, it is preferably provided that the newly added module control unit is provided, for example in the factory, with an individual control unit identification. The central control unit also stores the individual control unit identification of the new battery module, so that in the subsequent driving cycles the usage histograms can be provided with the authentication information matching the new battery module. For the case in which the battery module is replaced in a workshop or by the manufacturer, it can be ensured for example that following replacement of the module an initialization sequence is performed, which assigns a new module control unit identification to the new module memory unit and the identification is also stored in the central control unit. This ensures that the central control unit calculates the correct authentication information for the new module and the new module is able to correctly authenticate the usage histogram.

For the case in which the battery comprises a plurality of modules with associated module control units, for performing the step vi) it can be provided that the module control unit loads an existing histogram from its non-volatile memory, suitably combines the histogram received and validated from the central control unit and the existing histogram to form an updated histogram and stores it in the non-volatile memory of the module control unit. In addition to this, at least one additional information carrier can again be determined in a decentralized manner in each module control unit as described herein, being provided for a validity check of the updated histogram to be stored locally. The updated histogram and possibly the additional information carrier are then stored in the non-volatile memory of the module control unit. During read-out a check can thus be carried out as to whether a change has occurred of the histogram to be stored locally.

It is preferably provided that in the event of failures of validation an error message is transmitted from the respective module control unit to the central control unit. It can be provided that the central control unit then initiates further measures, such as for example blocking the battery management system or storing an error message, i.e. a message about the manipulation of the usage data for the relevant battery module. The module control unit can also store the usage histogram with a note regarding the manipulation. It can also be provided that in the event of a failure of validation of the module control unit, the manipulated usage histogram is discarded because of the manipulation and a counter is incremented. Said counter can be transmitted to the central control unit in the next driving cycle. As a result it can be provided that the central control unit decides that a maximum number of manipulations has been reached and can block or reduce usage of the battery, for example it can initiate a so-called limp home.

According to one embodiment, a check sum can be formed for the histogram as an additional information carrier. Such check sums are suitable for determining whether the histogram is corrupt or whether it can be used for the analysis of usage information. The check sum is for example formed by means of a cyclic redundancy check or by using a hash function. In the case of the cyclic redundancy check (CRC), a bit sequence of the histogram is divided by a specified generator polynomial, the so-called CRC polynomial modulo 2, wherein a remainder is left over. Said remainder is the CRC value that is added to the histogram. In addition or alternatively to this, a hash function, such as for example SHA-1, SHA-1 or SHA-3 can be provided, which as is well known maps the input quantity, in this case the relevant part of the histogram, onto a small target quantity, the hash values. Hash functions are suitable for confirming the integrity of the data. This means that it is practically impossible to produce a histogram by intentional modification that has the same hash value as a given histogram. The hash value can also be added to the histogram.

The presented methods can in particular be used with lithium-ion batteries and with nickel-metal hydride batteries. They are preferably used with a plurality of, and in particular with all of, the cells of one or a plurality of batteries that are essentially operated at the same time.

According to the invention, moreover a data structure is proposed with at least one histogram comprising frequency values of the occurrence of certain values of quantized usage data or values derived therefrom, and with at least one additional information carrier that is provided for a validity check of the histogram. The data structure is preferably produced when performing one of the described methods. For example, the data structure is read out by a computer device for maintenance and servicing purposes, for updating the stored information, for identification of erroneous information or for validation of the information.

According to the invention, furthermore a computer program is proposed, according to which one of the methods described herein is performed if the computer program is implemented on a programmable computer device. The computer program can for example be a module for implementing a device for providing or for reading out information for maintenance and servicing purposes for a battery unit and/or a module for implementing a battery management system of a vehicle. The computer program can be stored on a machine-readable memory medium, for example on a permanent or re-writable memory medium or in association with a computer device, for example on a portable memory device, such as a CD-ROM, a DVD, a USB stick or a memory card. In addition or alternatively, the computer program can be provided on a computer device, such as for example on a server or a cloud server, for downloading, for example over a data network, such as the Internet, or a communications link, such as for example a telephone line or a wireless connection.

According to the invention, moreover, a battery management system (BMS) is provided, with a unit for recording and quantization of usage data for a battery unit, a unit for generating or updating a histogram comprising frequency values of the occurrence of certain values of the individual quantized usage data or values derived therefrom, a unit for determining an additional information carrier that is provided for a validity check of the histogram, and a unit for storing the histogram and the at least one additional information carrier in a non-volatile memory.

The unit for storing the histogram and the additional information carrier in a non-volatile memory can both be disposed in a central control unit (BCU) and also in a module control unit (CPU). There can also be a plurality of units for storing the histograms and the additional information carrier, wherein a first unit can be associated with the BCU and further units with the individual CPUs.

The battery management system preferably comprises further units for the validation of histograms using the additional information carrier. Such units can be disposed both in the BCU and also in the CPU. Moreover, the battery management system preferably comprises communications units for transmitting data between the BCU and the CPU.

According to the invention, moreover, a battery, in particular a lithium-ion battery or a nickel-metal hydride battery, is provided that comprises a battery management system and that can be connected to a drive system of a motor vehicle, wherein the battery management system is designed and/or configured as described above to perform the method according to the invention.

The terms “battery” and “battery unit” are used in the present description adapted to the usual linguistic usage for an accumulator or an accumulator unit. The battery preferably comprises one or a plurality of battery units, which can comprise a battery cell, a battery module, a chain of modules or a battery pack. The battery cells are preferably combined spatially and connected together in a circuit for this, for example connected serially or in parallel to form modules. A number of modules can form a so-called battery direct converter (BDI) and a number of battery direct converters can form a battery direct inverter (BDI).

According to the invention, moreover, a motor vehicle is provided with such a battery, wherein the battery is connected to a drive system of the motor vehicle. The method is preferably used with electrically driven vehicles in which a number of battery cells are connected together to provide the necessary drive voltage.

### ADVANTAGES OF THE INVENTION

With the method the according to the invention, the manipulation of histograms in the memory of the control unit can be prevented, both in central control units and also in individual module control units. As a result, the unauthorized usage of battery packs outside of specifications by manipulation of the usage histogram can be detected. If a histogram has been stored in the memory of the relevant memory unit, and does not have the correct information carrier, then this is an indication of the manipulation of the usage histogram or of a faulty memory. The information carrier has no accurate knowledge of the specification of the calculation and a unique identification of the control unit cannot be forged. A plausible signature cannot be calculated by an attacker. The so-called Reverse Engineering of the signature calculation by means of sufficiently many known histogram-signature combinations can also be made very difficult, for example by using an individual control unit serial number.

The central battery control unit and the local module control units can be optionally configured and respond to the manipulation, for example with notes in the error memory or by blocking the battery. The control unit is moreover given the capability to recognize memory defects and it can respond accordingly and no longer use the faulty memory cells.

Moreover, the decentralized storage of the information on module control units is particularly advantageous. The usage histograms of removed modules can be read out and analyzed. The central module control unit is in principle not necessary for this. The replacement of modules has moreover no influence on the histograms of the other modules. The newly installed module is initialized with a blank histogram.

Furthermore, the use of individual keys for the individual module control units is particularly advantageous. For the unlikely case in which an attacker has decoded the protection of the usage information for a module, the most he can do is to manipulate the usage information of said module; all other modules remain protected as before.

A further advantage arises from the scalability of the system. The number of recorded measurement variables, i.e. the dimensions of the histogram, can be expanded as required. Thus large dimension histograms can be used, which for example provide information about how long a battery has been used with a certain combination of a defined state of charge, a defined temperature and a defined current flow. The method can moreover be used in parallel on different independent histograms.

### BRIEF DESCRIPTION OF THE FIGURES

Exemplary embodiments of the invention are represented in the figures and described in detail in the following description. In the figures

FIG. 1 shows an example of the updating of a two-dimensional histogram,

FIG. 2 shows an example of the manipulation-protected storage of histograms in a battery management system,

FIG. 3 shows a battery management system according to an embodiment of the invention,

FIG. 4 shows an example of the decentralized storage of histograms in a battery management system,

FIG. 5 shows an example of an attack scenario with histograms stored in a decentralized manner,

FIG. 6 shows an example of the manipulation-protected decentralized storage of histograms in a battery management system.

### EMBODIMENTS OF THE INVENTION

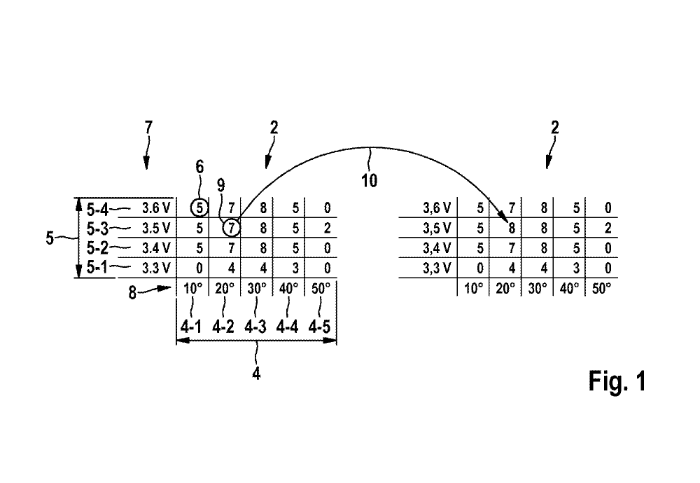

FIG. 1 shows a two-dimensional histogram 2 before and after an update step, which is represented here by way of example as an arrow 10. During the generation of the histogram 2 the temperature and the voltage are determined with a defined recording rate and the corresponding histogram value or frequency value 6 is increased by one. In the example an update step 10 is shown with an increase of the frequency of the measurement 9 of “20°/3.5 Volts”. It can be seen from the histogram 2 for example that after the update step 10 the battery was operated at 20° C. and 3.5 V voltage for 8 measurements, or even that the battery was operated no times at 0° C. The histogram 2 is also referred to as a usage histogram within the context of the invention.

In the example shown, a total interval 4 of temperatures from −10° C. to +50° C. is divided into 5 individual intervals 4-1, 4-2, . . . 4-5, wherein the individual intervals 4-1, 4-2, . . . 4-5 comprise by way of example an interval width of 10° C. The specified temperature values 8 can for example relate to the average values of the values given by the interval limits, or even to the value of the left or the right limit.

In the example shown, moreover, a total interval 5, which comprises here by way of example voltage values 7 of 3.3 V to 3.6 V, is divided into 4 individual intervals 5-1, 5-2, . . . 5-4, wherein the individual intervals 5-1, 5-2, . . . 5-4 comprise here by way of example an interval width of 0.1 V. The specified voltage values 7 can also relate to the average values of the values given by the interval limits, or even to the value of the left or right limit.

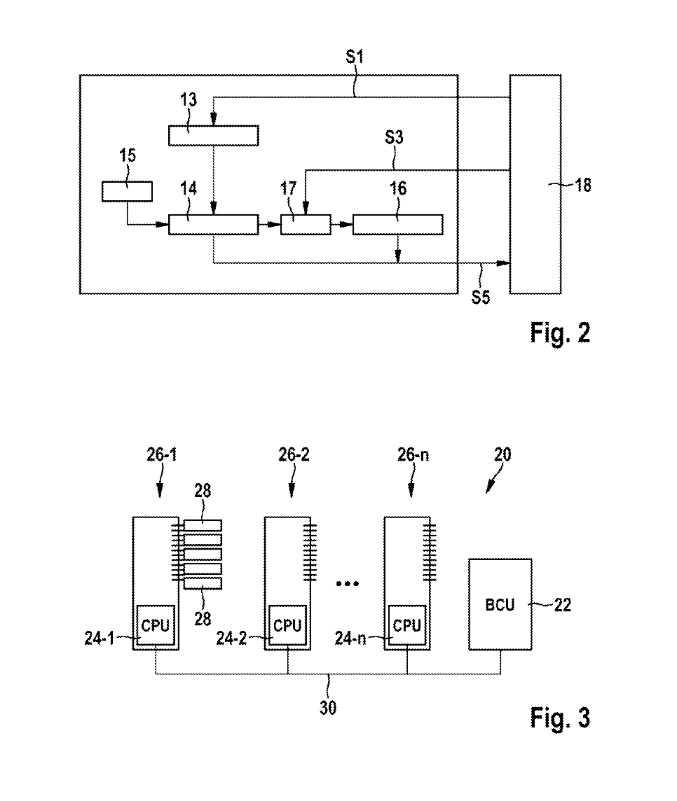

FIG. 2 shows an example of manipulation-protected storage of histograms in a control unit, such as for example in a central control unit of a battery management system or in a decentralized manner in a module control unit. In a first step S1 a unit 13 loads an existing histogram from a non-volatile memory 18 of the control unit. A further unit 15 records and quantizes battery unit usage data and forms therefrom a histogram for the current driving cycle, wherein many of the individual update steps 10 described with reference to FIG. 1 are usually carried out during this. The recorded quantized usage data and the existing histogram are fed to another unit 14, which produces the updated histogram therefrom, for example by adding the two histograms component by component.

The unit 14 for producing the histogram transmits the updated histogram to a unit 17 for determining an additional information carrier. In a step S3 for example, the unit 17 for determining the additional information carrier determines the serial number of the control unit from the non-volatile memory 18 of the control unit and by means of a one-way function f(x,y) calculates an additional information carrier 16 that is provided for a validity check of the histogram from the serial number and the updated histogram, for example by means of an XOR function over all entries of the histogram. In a further step S5 the updated histogram and the additional information carrier 16 are stored in the non-volatile memory 18 of the relevant control unit.

The one-way function f(x,y)→z is preferably defined with such properties that its function value z is simple to calculate and reversal of the function is very complex. Examples of such one-way functions are to be found in cryptography, for example hash functions, in particular SHA-1, SHA-2 or SHA-3, or as the multiplication of primary numbers. The one-way function is implemented in the battery management system. In the one-way function f(x,y)→z, the value y is a unique control unit identification, for example a serial number of the control unit. With the value y it is ensured that the same one-way function gives different results in different control units. The input value x is the histogram. For example, all histogram entries are combined by XOR to form a value that is then included in the signature calculation together with the value y. The histogram is then provided with the authentication information, a so-called signature, which can be referred to within the context of the invention as an additional information carrier 16. Said signature, for example a 32-bit value, is calculated from the histogram and the unique data element of the control unit and is stored together with the histogram. Without knowledge of the specification of the calculation, an attacker cannot produce and store in the control unit a plausible combination of usage histogram and matching signature. The derivation of the specification of the calculation by reading out histograms and signatures after each driving cycle is made very difficult by the use of the individual control unit key.

In the case of damage/warranty, the histogram, the signature and the serial number are read out of the non-volatile memory 18 of the control unit. A signature is again calculated from the histogram and the serial number. If said signature matches the stored signature from the control unit, then there is no manipulation of the usage histogram in the control unit. If the signatures do not match, the histogram in the control unit has been manipulated.

FIG. 3 shows a battery management system 20 according to one embodiment of the present invention. The battery management system comprises a central control unit 22, which can also be referred to as a BCU (Battery Control Unit), and a number of battery modules 26-1, 26-2, . . . 26-n, each of which comprises dedicated module control units 24-1, 24-2, . . . 24-n, which are also referred to as CMCs (Cell Module Controller). A plurality of battery cells 28 are associated with each module 26-1, 26-2, . . . 26-n, wherein said battery cells are usually connected in series and sometimes additionally in parallel in order to achieve the required power and energy data with the battery system. The individual battery cells 28 are for example lithium-ion batteries with a voltage range from 2.8 to 4.2 V. The communications between the central control unit 22 and the module control units 26-1, 26-2, . . . 26-n are carried out by means of a communications channel 30, for example by means of a CAN bus.

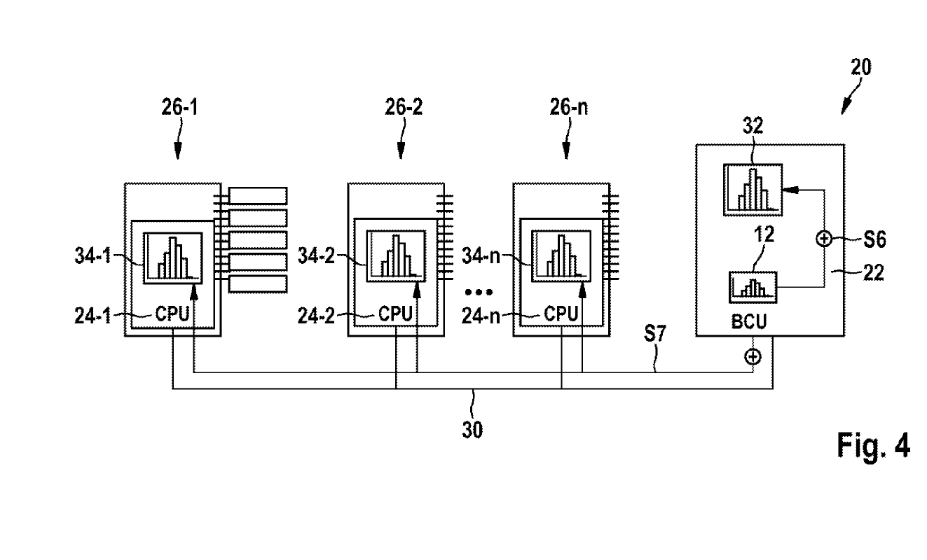

FIG. 4 shows the decentralized storage of histograms in a battery management system 20. The battery management system 20 can be structured as described with reference to FIG. 3 and comprises a central control unit 22 and module control units 24. A suitable recording and quantization module (not shown), which can be structured as described with reference to FIG. 2, produces a current histogram 12 regarding the usage of the battery during the last driving cycle. In a step S6 the current histogram 12 is added to an overall histogram 32, which is stored in a non-volatile memory of the central control unit 22. An additional information carrier can be determined here, which enables validation of the overall histogram 32 in the non-volatile memory of the central control unit 22, as described with reference to FIG. 2. In the context of warranty claims, the overall histogram 32 can be read out of the non-volatile memory of the central control unit 22 and used for analysis of the battery usage.

In addition, the usage histogram 12 of the current driving cycle is transmitted to the module control units 24 in a further step S7. The current histogram 12 is added to the usage histograms 34 stored locally and in a decentralized manner in the module control units 24, wherein this can be carried out as described with reference to FIG. 2. In particular, it can be provided that further additional information carriers are added to the histograms 34 stored in the module control units 24, which in turn are provided for a validity check of the histograms 34. The transmission of the current histogram 12 to the individual module control units 24 can be carried out by means of the communications channel 30.

In the case of a warranty, both the overall histogram of the central control unit 22 and also the histograms 34 of the individual modules 26 can be read out. Also in a case in which individual modules 26 are replaced, the usage histogram 32 in the central control unit 22 gives information about the usage of the entire battery pack. In the case of the replacement of modules 26, the usage histograms 34 in the modules 26 provide information about the detailed usage of the respective module 26. Removed modules can be analyzed individually by the manufacturer without access having to be made to the central control unit 22. It can preferably be provided that newly installed modules 26 only record usage data from the time of the installation.

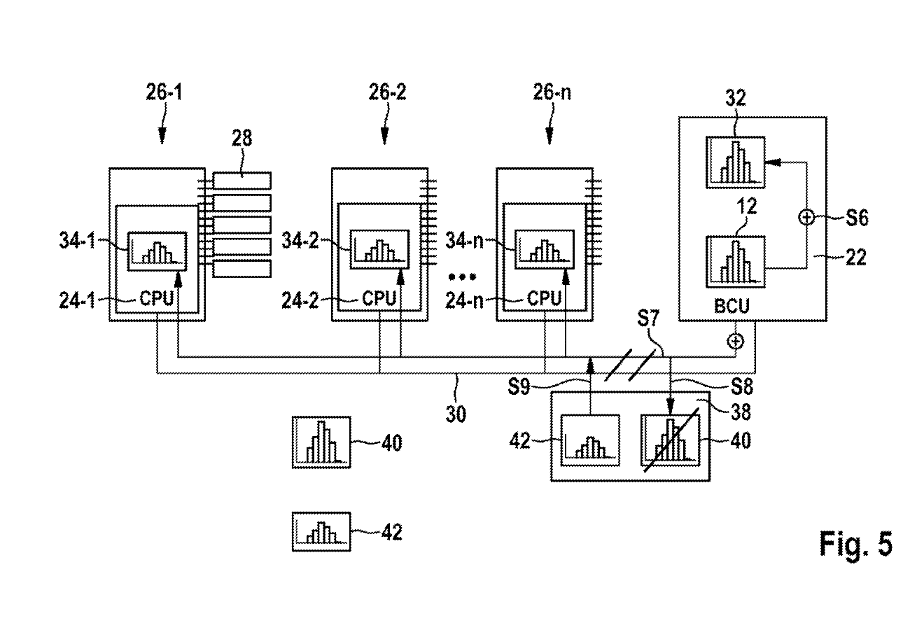

FIG. 5 shows an example of the interception of transmitted data and replacement of the data with manipulated data by an attacker 38. The system can be designed as described with reference to FIG. 4, in particular after each driving cycle in a step S6 the central control unit 22 stores the current histogram 12 in the overall histogram 32 and transmits it in a step S7 to the decentralized module control units 24, which add the current histogram 12 to the histogram 34 stored in the module control unit 24.

In the example shown, the attacker 38 intercepts the data 40 transmitted in step 7 in a step S8 and replaces said data with manipulated data 42 in a further step S9. During this the attacker 38 cuts the connection via the communications channel 30 between the central control unit 22 and the module control units 24. It can be provided that any communication apart from the usage information is forwarded unaltered. However, once the current histogram 12 is sent from the central control unit 22 to the module control units 24 following a driving cycle, the same is intercepted and replaced by manipulated usage information 42. In FIG. 5 it is shown how a histogram 40 with high usage is intercepted and replaced by a histogram 42 with lower usage. During this for example, regions can be hidden in which the battery was not used or in total a reduced usage can be transmitted, so that a false life or a false age of the battery and of the battery module are calculated. In cases of warranty claims, it is difficult to impossible to draw conclusions regarding the actual battery usage. The usage histogram 32 of the central control unit 22 does give information about the usage of the entire battery, but since modules 26 with module control units 24 can have been replaced, how much the present modules 26 have actually been used cannot be tracked.

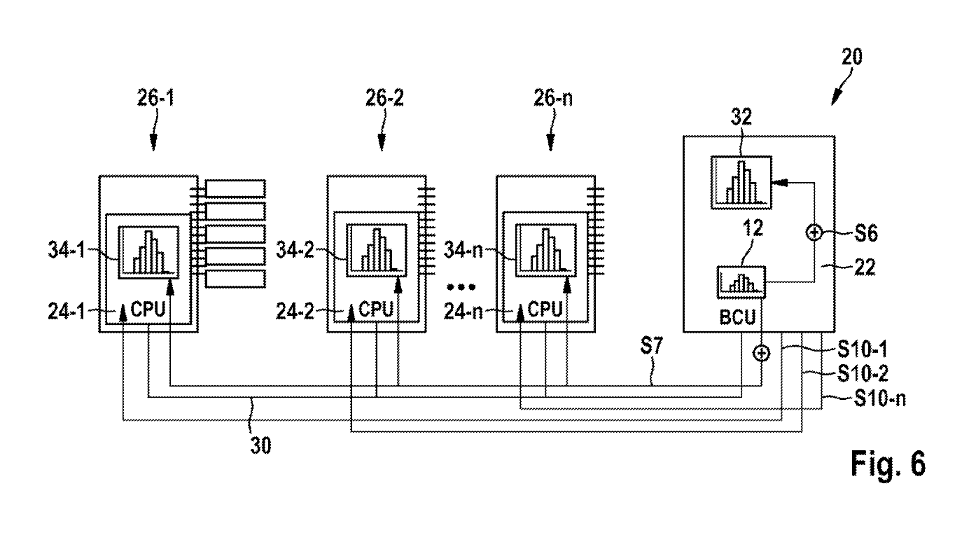

FIG. 6 shows an example of manipulation protection according to the invention for decentralized storage of histograms in the battery management system 20. The system can be designed as described with reference to FIGS. 3-5. During a driving cycle a usage histogram for the driving cycle is produced by the central control unit 22, is added to an overall histogram 32 and in a step S6 is stored in a non-volatile memory of the central control unit 22. In addition, in a step S7 the histogram produced 12 is for example communicated by means of the communications bus 30 from the central control unit 22 to the module control units 24. In addition, in a step S10 the additional information carrier is transmitted from the central control unit 22 to the module control units 24 in each case. As the additional information carrier is preferably different for each module 26, said step is divided into individual steps S10-1, S10-2, . . . S10-n. In particular, according to a preferred embodiment it can be provided that for each module control unit 24 the central control unit 22 calculates an individual additional information carrier from the current usage histogram 12 and the individual key of the module control unit 24, wherein the individual key of the module control unit 24 is stored in the central control unit 22. During this a check sum is calculated using the individual key of the module control unit 24 and the individual values of the histogram 12. In particular, the use of a one-way function can be provided, as described with reference to FIG. 2 with input parameters of the histogram 12 and of the individual key. Alternatively or additionally, it can be provided that asymmetrical encoding is carried out, for example by means of public key encryption, wherein the keys for authentication are derived from the individual module control unit keys.

In the individual module control units 24-1, 24-2, . . . 24-n, the transmitted usage histogram 12 is verified using the additional information carrier, i.e. using the individual authentication information. Each module control unit 24 checks the additional information carrier during this using its individual key and the usage histogram 12. There are the following possibilities:
a) The authentication information communicated by the central control unit 22 matches the self-calculated authentication information: The data from the central control unit 22 are not manipulated. The usage histogram 12 of the last driving cycle is added to the already stored usage histogram 34. The histogram 34 respectively stored in the module control unit 24 is read out for this from the non-volatile memory of the module control unit 24, the histogram 12 of the driving cycle currently in progress is added and the result is again stored in the non-volatile memory of the module control unit 24.
b) The authentication information communicated from the central control unit 22 does not match the authentication information calculated by the module control unit 24: the data were manipulated between the central control unit 22 and the module control unit 24 (for example by an attacker). The proposed measures can include:
   i) Discarding the usage histogram and sending a message to the central control unit 22 regarding the manipulation of the data. The central control unit 22 initiates further measures: blocking the battery management system, storing the manipulation of the usage data for the affected module 26, etc.
   i) The module control unit 24 stores the usage data with a note of the manipulation.
   ii) The module control unit 24 discards the usage data because of the manipulation and increments a counter. Said counter is transmitted to the central control unit 22 in the next driving cycle. The central control unit 22 can decide that a maximum number of manipulations has been reached and can block/reduce usage of the battery (“limp home”).

The invention is not limited to the exemplary embodiments described here and the aspects highlighted therein. Rather, within the scope specified by the claims a number of variations are possible, which lie within the context of action by persons skilled in the art.

1. A method for providing information for maintenance and servicing purposes for a battery including (i) a control unit with a non-volatile memory, and (ii) a plurality of battery units, the method comprising:
recording and quantizing usage data of the plurality of battery units;
forming a histogram comprising frequency values of an occurrence of certain values of individual quantized usage data or values derived therefrom;
determining at least one additional information carrier that is provided for a validity check of the histogram; and
storing the histogram and the additional information carrier in the non-volatile memory of the control unit.

2. The method as claimed in claim 1, further comprising:
determining the at least one additional information carrier as is a check sum using the histogram and an individual key of the control unit.

3. The method as claimed in claim 1, wherein the battery comprises a plurality of modules with associated module control units, and the method further comprises:
storing the histogram and a further additional information carrier in a non-volatile memory of at least one associated module control unit.

4. A method for providing information for maintenance and servicing purposes for a battery including (i) at least one battery module with an associated module control unit, and (ii) a central control unit, wherein the associated module control unit includes a non-volatile memory, the method comprising:
recording and quantizing usage data of a plurality of battery units;
forming a histogram comprising frequency values of an occurrence of certain values of individual quantized usage data or values derived therefrom;
determining, with the central control unit, at least one additional information carrier that is provided for a validity check of the histogram;
transmitting the histogram and the at least one additional information carrier from the central control unit to the associated module control unit;
validating the histogram with the associated module control unit using the at least one additional information carrier; and
storing the histogram in the non-volatile memory of the associated module control unit.

5. The method as claimed in claim 4, further comprising:
determining the at least one additional information carrier as a check sum using the histogram and an individual key of the module control unit.

6. The method as claimed in claim 4, wherein transmitting the histogram further comprises:
loading an existing histogram from the non-volatile memory of the associated module control unit;
suitably combining the histogram received and validated by the central control unit and the existing histogram to form an updated histogram; and
storing the histogram received and validated by the central control unit and the existing histogram in the non-volatile memory.

7. The method as claimed in claim 4, further comprising:
transmitting an error message or a counter from the associated module control unit to the central control unit if a failure of validation occurs.

8. The method as claimed in claim 4, further comprising:
producing a data structure during performance of the method, the data structure including the histogram, and the at least one additional information carrier; and
reading out the data structure with a computer device.

9. The method as claimed in claim 4, wherein a computer program is configured to perform the method when the computer program is implemented on a programmable computer device.

10. A battery management system comprising:
a first unit configured to record and to quantize usage data of a battery unit;
a second unit configured to produce a histogram comprising frequency values of an occurrence of certain values of individual quantized usage data or values derived therefrom;
a third unit configured to determine an additional information carrier that is provided for a validity check of the histogram; and
a fourth unit configured to store the histogram and the additional information carrier in a non-volatile memory.

11. The battery management system of claim 10, wherein the battery management system is included in a battery that also includes a plurality of battery cells and battery management system.

12. The battery management system of claim 11, wherein the battery is configured for connection to a drive system of a motor vehicle.
